(19) United States
(12) Patent Application Publication
(10) Pub. No.: US 2024/0413605 A1
(43) Pub. Date: Dec. 12, 2024

(54) LIGHT-EMITTING ELEMENT ARRAY

(71) Applicant: SONY SEMICONDUCTOR SOLUTIONS CORPORATION, Kanagawa (JP)

(72) Inventors: Yukihisa IGARASHI, Kumamoto (JP); Takashi SUGIYAMA, Kumamoto (JP); Motoi KIMURA, Kanagawa (JP)

(21) Appl. No.: 18/696,797

(22) PCT Filed: Oct. 5, 2022
(86) PCT No.: PCT/JP2022/037219

§ 371 Date: Mar. 28, 2024

(30) Foreign Application Priority Data
Oct. 27, 2021 (JP) 2021-175448

(51) Int. Cl. H01S 5/042; H01S 5/42

(52) U.S. Cl. CPC H01S 5/04256; H01S 5/423

(57) ABSTRACT

[Object] To provide a light-emitting element array having a wiring structure that enables an increase in response speed of a light-emitting element.

[Solving Means] A light-emitting element array according to the present technology includes: a light-emitting element group; a first wire; and a second wire. The light-emitting element group forms a light-emitting element surface on which a plurality of light-emitting elements is arranged in a planar shape and includes first light-emitting element columns, first light-emitting elements included in the plurality of light-emitting elements being arranged along a first direction parallel to the light-emitting element surface in each of the first light-emitting element columns. The first wire extends along the first direction and is electrically connected to each of the first light-emitting elements in each of the first light-emitting element columns, a current flowing through the first wire in a first orientation parallel to the first direction. The second wire extends along the first direction and is electrically connected to each of the first light-emitting elements in each of the first light-emitting element columns, a current flowing through the second wire in a second orientation parallel to the first direction and opposite to the first orientation.

### TECHNICAL FIELD

The present technology relates to a light-emitting element array in which a plurality of light-emitting elements is arranged.

### BACKGROUND ART

A light-emitting element such as a vertical cavity surface emitting laser (VCSEL) element is often used for a light-emitting element array in which a plurality of light-emitting elements is arranged. Here, in the light-emitting element array, wiring of each light-emitting element causes a problem in accordance with the number and density of light-emitting elements constituting the array.

For example, Patent Literature 1 discloses a semiconductor near-field light source in which a row wire and a column wire are connected to each of a large number of light-emitting elements arranged in a matrix. The row wire and the column wire extend in directions perpendicular to each other and are provided to intersect with each other. By applying a voltage to an arbitrary row wire and an arbitrary column wire, the light-emitting element located at the intersection of the row wire and the column wire to which the voltage is applied emits light.

### CITATION LIST

### Patent Literature

Patent Literature 1: Japanese Patent Application Laid-open No. 2000-332354

### DISCLOSURE OF INVENTION

### Technical Problem

However, in the light-emitting element array as described in Patent Literature 1, a decrease in response speed of the light-emitting element becomes a problem. In particular, in sensing applications, the response speed of the light-emitting element is an important parameter and is desired to be improved.

In view of the circumstances as described above, it is an object of the present technology to provide a light-emitting element array having a wiring structure that enables an increase in response speed of a light-emitting element.

### Solution to Problem

In order to achieve the above-mentioned object, a light-emitting element array according to an embodiment of the present technology includes: a light-emitting element group; a first wire; and a second wire.

The light-emitting element group forms a light-emitting element surface on which a plurality of light-emitting elements is arranged in a planar shape and includes first light-emitting element columns, first light-emitting elements included in the plurality of light-emitting elements being arranged along a first direction parallel to the light-emitting element surface in each of the first light-emitting element columns.

The first wire extends along the first direction and is electrically connected to each of the first light-emitting elements in each of the first light-emitting element columns, a current flowing through the first wire in a first orientation parallel to the first direction.

The second wire extends along the first direction and is electrically connected to each of the first light-emitting elements in each of the first light-emitting element columns, a current flowing through the second wire in a second orientation parallel to the first direction and opposite to the first orientation.

The light-emitting element group may further include second light-emitting element columns, second light-emitting elements included in the plurality of light-emitting elements being arranged along a second direction parallel to the light-emitting element surface in each of the second light-emitting element columns, and the light-emitting element array may further include:
a third wire that extends along the second direction and is electrically connected to each of the second light-emitting elements in each of the second light-emitting element columns, a current flowing through the third wire in a third orientation parallel to the second direction; and
a fourth wire that extends along the second direction and is electrically connected to each of the second light-emitting elements in each of the second light-emitting element columns, a current flowing through the fourth wire in a fourth orientation parallel to the second direction and opposite to the third orientation.

The first direction and the second direction may be orthogonal to each other.

The light-emitting element array may further include:
a first insulation layer formed of an insulating material; and
a second insulation layer formed of an insulating material,
the first insulation layer being disposed on the light-emitting element surface,
the first wire and the second wire being disposed on the first insulation layer,
the second insulation layer being formed on the first insulation layer, the first wire, and the second wire,
the third wire and the fourth wire being disposed on the second insulation layer.

The first wire may be electrically connected to each of the first light-emitting elements via a first current injection port provided in the first insulation layer,
the second wire may be electrically connected to each of the first light-emitting elements via a second current injection port provided in the first insulation layer,
the third wire may be electrically connected to each of the second light-emitting elements via a third current injection port provided in the first insulation layer and the second insulation layer, and
the fourth wire may be electrically connected to each of the second light-emitting elements via a fourth current injection port provided in the first insulation layer and the second insulation layer.

The first wire may have a first superimposition region that is superimposed on the first light-emitting elements as viewed from a direction perpendicular to the light-emitting element surface, the first current injection port being provided within the first superimposition region as viewed from the direction,
the second wire may have a second superimposition region that is superimposed on the first light-emitting elements as viewed from a direction perpendicular to the light-emitting element surface, the second current injection port being provided within the second superimposition region as viewed from the direction,
the third wire may have a third superimposition region that is superimposed on the second light-emitting elements as viewed from a direction perpendicular to the light-emitting element surface, the third current injection port being provided within the third superimposition region as viewed from the direction, and
the fourth wire may have a fourth superimposition region that is superimposed on the second light-emitting elements as viewed from a direction perpendicular to the light-emitting element surface, the fourth current injection port being provided within the fourth superimposition region as viewed from the direction.

The light-emitting element array may further include
a first electrode pad that is electrically connected to the first wire and the second wire and includes a first portion and a second portion, the first portion and the second portion being located in opposite directions via the light-emitting element group in the first direction,
the first wire being connected to the first portion and spaced apart from the second portion,
the second wire being connected to the second portion and spaced apart from the first portion.

The light-emitting element array may further includes:
a first electrode pad that is electrically connected to the first wire and the second wire and includes a first portion and a second portion, the first portion and the second portion being located in opposite directions via the light-emitting element group in the first direction; and
a second electrode pad that is electrically connected to the third wire and the fourth wire and includes a third portion and a fourth portion, the third portion and the fourth portion being located in opposite directions via the light-emitting element group in the second direction,
the first wire being connected to the first portion and spaced apart from the second portion,
the second wire being connected to the second portion and spaced apart from the first portion,
the third wire being connected to the third portion and spaced apart from the fourth portion,
the fourth wire being connected to the fourth portion and spaced apart from the third portion.

Each of the plurality of light-emitting elements may be a vertical cavity surface emitting laser element.

### BRIEF DESCRIPTION OF DRAWINGS

FIG. 1 is a plan view of a light-emitting element array according to an embodiment of the present technology.

FIG. 2 is an enlarged plan view of the light-emitting element array.

FIG. 3 is an enlarged plan view of the light-emitting element array.

FIG. 4 is a plan view of a light-emitting element group included in the above light-emitting element array.

FIG. 5 is a cross-sectional view (taken along the line A in FIG. 4) of the above light-emitting element group.

FIG. 6 is a cross-sectional view (taken along the line B in FIG. 4) of the above light-emitting element group.

FIG. 7 is a plan view of a light-emitting element constituting the light-emitting element array.

FIG. 8 is a cross-sectional view of the light-emitting element.

FIG. 9 is a schematic diagram showing arrangement of first light-emitting elements and second light-emitting elements constituting the above light-emitting element array.

FIG. 10 is a plan view of a first electrode pad included in the above light-emitting element array.

FIG. 11 is a plan view of a second electrode pad included in the above light-emitting element array.

FIG. 12 is a plan view showing the first light-emitting elements, first wires, second wires, and the first electrode pad included in the above light-emitting element array.

FIG. 13 is a plan view showing the first wires, the second wires, and the first electrode pad included in the above light-emitting element array.

FIG. 14 is a plan view showing the first light-emitting elements, the first wire, and the second wire included in the above light-emitting element array.

FIG. 15 is a plan view showing the second light-emitting elements, third wires, fourth wires, and the second electrode pad included in the above light-emitting element array.

FIG. 16 is a plan view showing the second light-emitting elements, the third wires, and the fourth wires included in the above light-emitting element array.

FIG. 17 is a plan view showing the second light-emitting elements, the third wire, and the fourth wire included in the above light-emitting element array.

FIG. 18 is a schematic diagram showing a cross section of the above light-emitting element array.

FIG. 19 is a cross-sectional view (taken along the line C in FIG. 18) of the above light-emitting element array.

FIG. 20 is a cross-sectional view (taken along the line D in FIG. 18) of the above light-emitting element array.

FIG. 21 is a cross-sectional view (taken along the line E in FIG. 18) of the above light-emitting element array.

FIG. 22 is a cross-sectional view (taken along the line F in FIG. 18) of the above light-emitting element array.

FIG. 23 is a cross-sectional view of a partial configuration of FIG. 22.

FIG. 24 is a schematic diagram showing a positional relationship between the first light-emitting element, a first current injection port, and a second current injection port included in the above light-emitting element array.

FIG. 25 is a cross-sectional view (taken along the line G in FIG. 18) of the above light-emitting element array.

FIG. 26 is a cross-sectional view of a partial configuration of FIG. 25.

FIG. 27 is a schematic diagram showing a positional relationship between the second light-emitting element, a third current injection port, and a fourth current injection port included in the above light-emitting element array.

FIG. 28 is a schematic diagram showing orientations of currents flowing through the first wire and the second wire included in the above light-emitting element array.

FIG. 29 is a schematic diagram showing orientations of currents flowing through the third wire and the fourth wire included in the above light-emitting element array.

FIG. 30 is a plan view of a light-emitting element array according to Comparative Example.

FIG. 31 is a schematic diagram showing orientations of currents flowing through a wire of the light-emitting element array according to Comparative Example.

### MODE(S) FOR CARRYING OUT THE INVENTION

A light-emitting element array according to an embodiment of the present technology will be described.

### [Configuration of Light-Emitting Element Array]

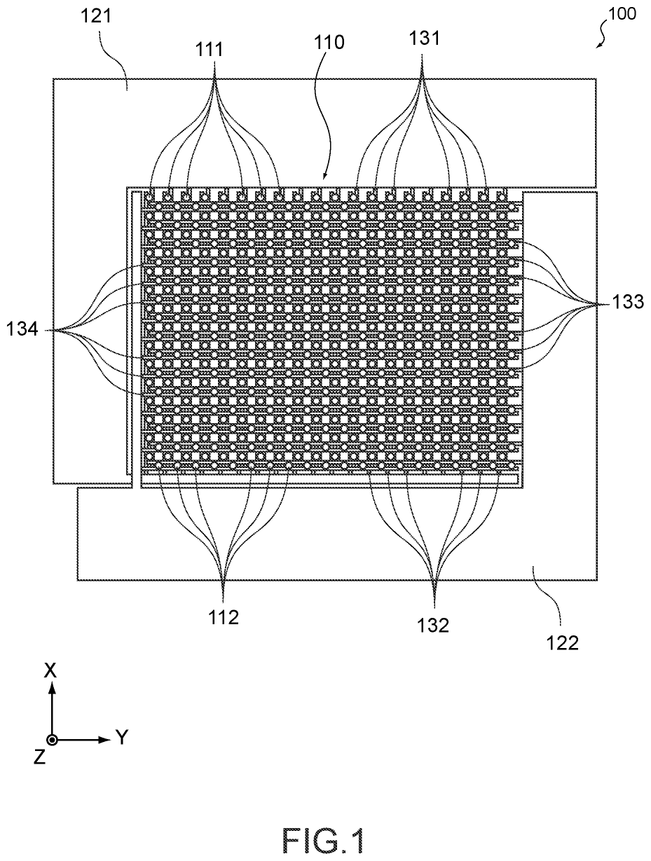

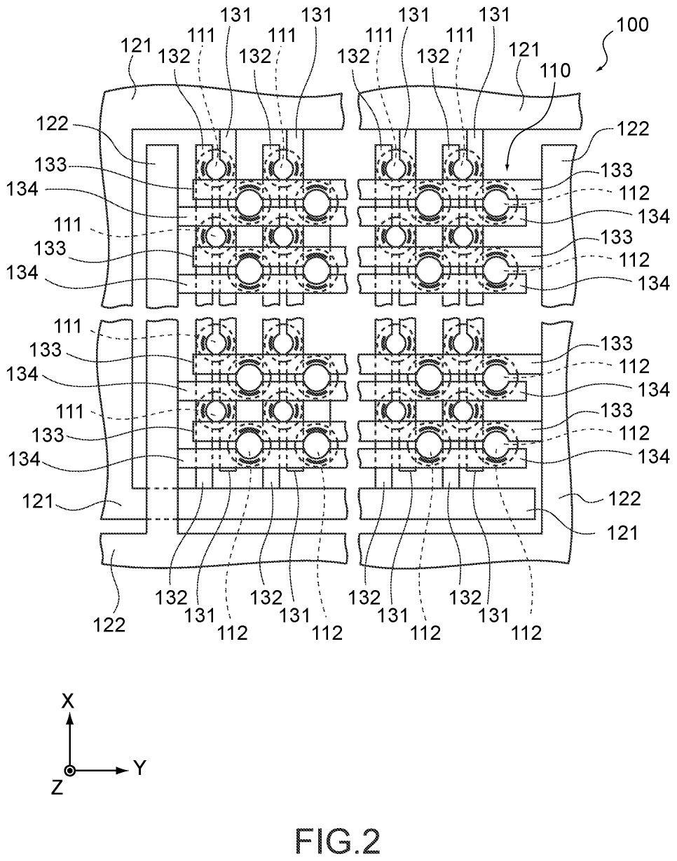

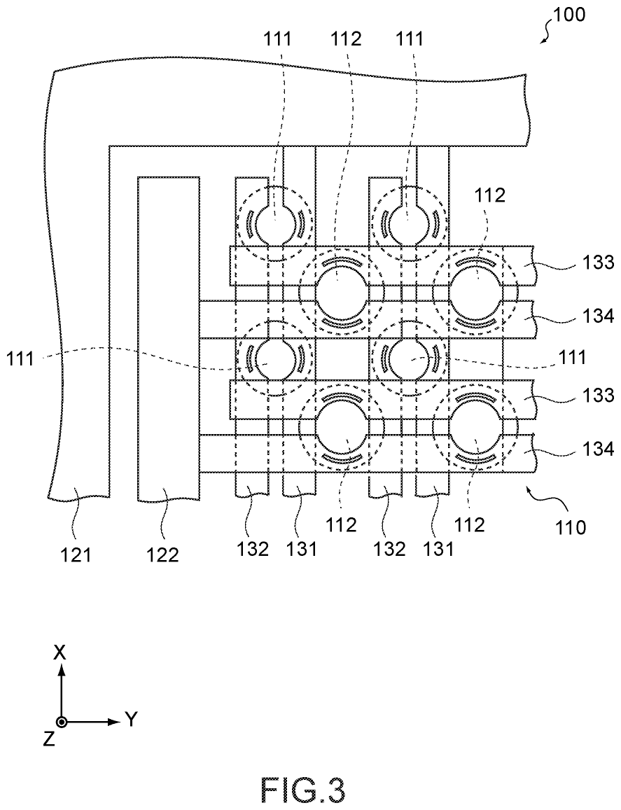

FIG. 1 is a plan view of a light-emitting element array 100 according to this embodiment, and FIG. 2 and FIG. 3 are each an enlarged view of FIG. 1. As shown in these figures, the light-emitting element array 100 includes first light-emitting elements 111, second light-emitting elements 112, a first electrode pad 121, a second electrode pad 122, first wires 131, second wires 132, third wires 133, and fourth wires 134. The first light-emitting elements 111 and the second light-emitting elements 112 constitute a light-emitting element group 110.

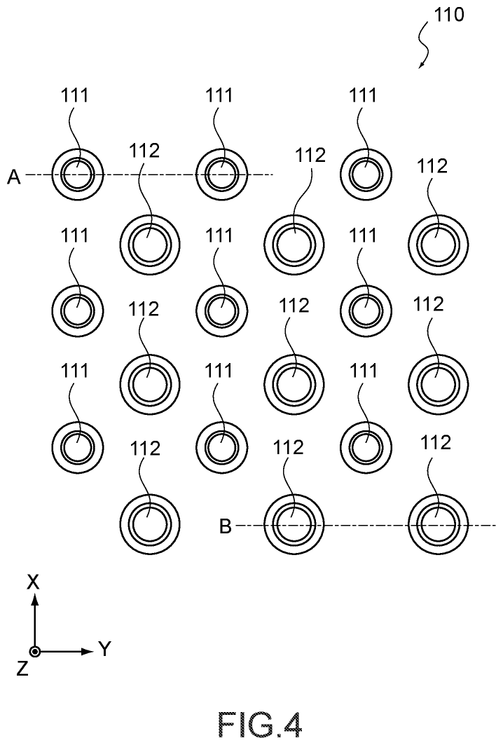

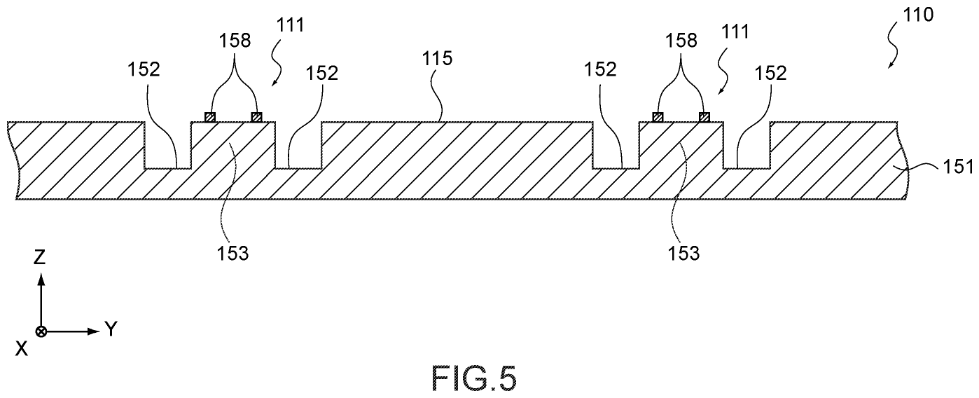

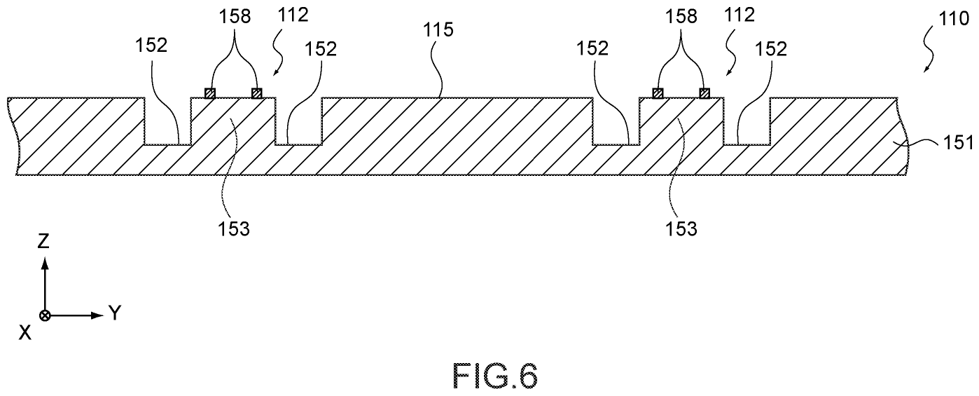

FIG. 4 is a plan view of the light-emitting element group 110. As shown in the figure, the light-emitting element group 110 includes a plurality of first light-emitting elements 111 and a plurality of second light-emitting elements 112 arranged in a planar shape. FIG. 5 and FIG. 6 are each a cross-sectional view of the light-emitting element group 110. FIG. 5 is a cross-sectional view taken along the line A in FIG. 4, and FIG. 6 is a cross-sectional view taken along the line B in FIG. 4. Hereinafter, as shown in FIGS. 5 and 6, a surface on which the first light-emitting elements 111 and the second light-emitting elements 112 are arranged will be referred to as a light-emitting element surface 115, one direction parallel to the light-emitting element surface 115 will be referred to as an X direction, and a direction parallel to the light-emitting element surface 115 and orthogonal to the X direction will be referred to as a Y direction. That is, the light-emitting element surface 115 is parallel to the X-Y plane. Further, a direction perpendicular to the light-emitting element surface 115 will be referred to as a Z direction. Note that the number of first light-emitting elements 111 and the number of second light-emitting elements 112 are not particularly limited, and may each be, for example, several tens to several thousands.

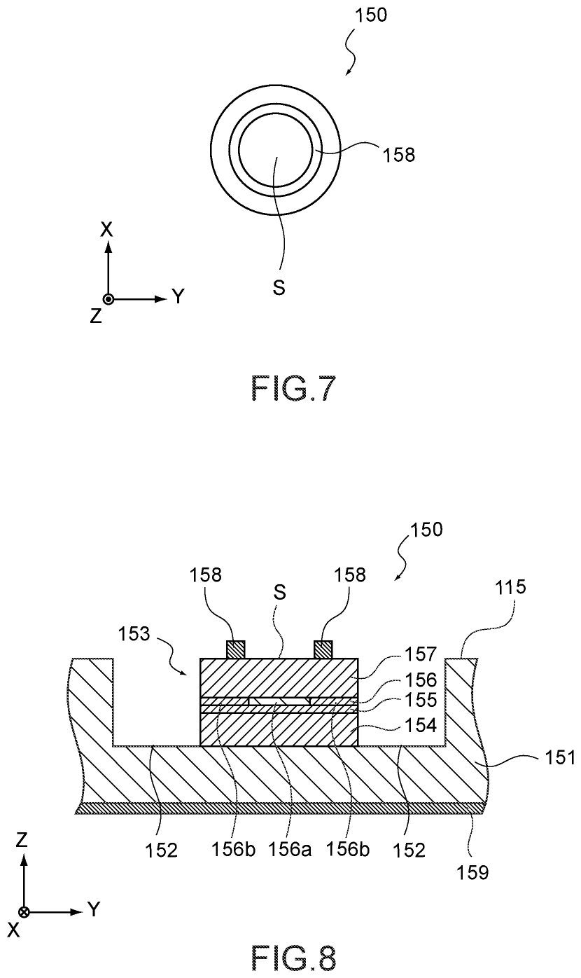

The first light-emitting element 111 and the second light-emitting element 112 can be light-emitting elements having the same configuration. FIG. 7 is a plan view of a light-emitting element 150 capable of forming the first light-emitting element 111 and the second light-emitting element 112, and FIG. 8 is a cross-sectional view of the light-emitting element 150. The light-emitting element 150 is a vertical cavity surface emitting laser (VCSEL) element. As shown in FIG. 8, the light-emitting element 150 is surrounded by an annular recessed portion 152 provided in a substrate 151 and has a mesa structure in which a mesa (plateau shape) 153 is formed.

As shown in FIG. 8, the light-emitting element 150 includes an n-type DBR layer 154, an active layer 155, a current confinement layer 156, a p-type DBR layer 157, a p-electrode 158, and an n-electrode 159. The n-type DBR layer 154, the active layer 155, the current confinement layer 156, and the p-type DBR layer 157 are stacked on the substrate 151 in this order.

The n-type DBR layer 154 is formed of an n-type semiconductor material, functions as a DBR (Distributed Bragg Reflector), and reflects light having specific wavelength (hereinafter, a wavelength A). The n-type DBR layer 154 constitutes an optical resonator for laser oscillation together with the p-type DBR layer 157. The active layer 155 is provided between the n-type DBR layer 154 and the p-type DBR layer 157, and emits and amplifies spontaneous emitted light. The active layer 155 can include a plurality of layers obtained by alternately stacking a quantum well layer and a barrier layer.

The current confinement layer 156 is provided in the vicinity of the active layer 155 and imparts a confinement action to a current. The current confinement layer 156 includes a non-oxidized region 156a and an oxidized region 156b. The non-oxidized region 156a is provided in the center of the current confinement layer 156 and the oxidized region 156b is provided around the non-oxidized region 156a. The oxidized region 156b can be formed by performing oxidation treatment from the outer periphery side of a mesa 153 via the recessed portion 152.

The p-type DBR layer 157 is formed of a p-type semiconductor material, functions as a DBR, and reflects light having the wavelength A. The p-type DBR layer 157 constitutes an optical resonator for laser oscillation together with the n-type DBR layer 154. The p-electrode 158 is provided on the surface of the mesa 153 and is electrically connected to the p-type DBR layer 157. As shown in FIG. 7, the p-electrode 158 has an annular shape. The n-electrode 159 is provided on the surface of the substrate 151 on the side opposite to the light-emitting element 150 and is electrically connected to the n-type DBR layer 154 via the substrate 151.

The light-emitting element 150 has the configuration as described above. In the light-emitting element 150, when a voltage is applied between the p-electrode 158 and the n-electrode 159, a current flows between the p-electrode 158 and the n-electrode 159. The current is subjected to a current confinement action by the current confinement layer 156 and is injected into the active layer 155 in the vicinity of the non-oxidized region 156a. This injected current causes spontaneously emitted light in the active layer 155, and the spontaneously emitted light is reflected by the n-type DBR layer 154 and the p-type DBR layer 157. Of the spontaneously emitted light, a component of the oscillation wavelength λ forms a standing wave between the n-type DBR layer 154 and the p-type DBR layer 157 and is amplified by the active layer 155. When the injected current exceeds a threshold value, laser oscillation of light forming a standing wave occurs, and a laser beam passes through the p-type DBR layer 157 and is emitted. In FIG. 7 and FIG. 8, a surface from which a laser beam is emitted is shown as a light-emitting surface S. The p-electrode 158 is provided around the light-emitting surface S.

Note that the configuration of the light-emitting element 150 is not limited to the one shown here. For example, the n-type and the p-type in the light-emitting element 150 may be reversed. Further, although the above configuration shows the configuration of a surface emission type VCSEL element, the light-emitting element 150 may be a backside emission type VCSEL. Further, the light-emitting element 150 is not limited to the VCSEL and may be a light-emitting element formed of a semiconductor such as an LED (Light Emitting Diode).

As shown in FIG. 4, the light-emitting element array 100 can be a light-emitting element array in which the first light-emitting elements 111 and the second light-emitting elements 112 having the configuration of the light-emitting element 150 are arranged. In the first light-emitting element 111 and the second light-emitting element 112, the size of the mesa 153 may differ as shown in FIG. 4 or the size of the mesa 153 may be the same.

The first light-emitting element 111 and the second light-emitting element 112 have the configurations as described above. Here, the first light-emitting element 111 and the second light-emitting element 112 are configured to be capable of emitting light independently of each other. Specifically, as shown in FIG. 8, the n-electrode 159 is uniformly formed on the back surface of the substrate 151 and is a common electrode between the first light-emitting element 111 and the second light-emitting element 112.

Meanwhile, the p-electrode 158 is provided on the mesa 153 and is an independent electrode for each of the first light-emitting elements 111 and the second light-emitting elements 112. Therefore, by applying a voltage between the p-electrode 158 provided in the first light-emitting element 111 and the n-electrode 159, the first light-emitting element 111 can be caused to emit light. By applying a voltage between the p-electrode 158 provided in the second light-emitting element 112 and the n-electrode 159, the second light-emitting element 112 can be caused to emit light. Note that in the figures other than FIG. 8, illustration of the layer structure of the light-emitting element 150 is omitted.

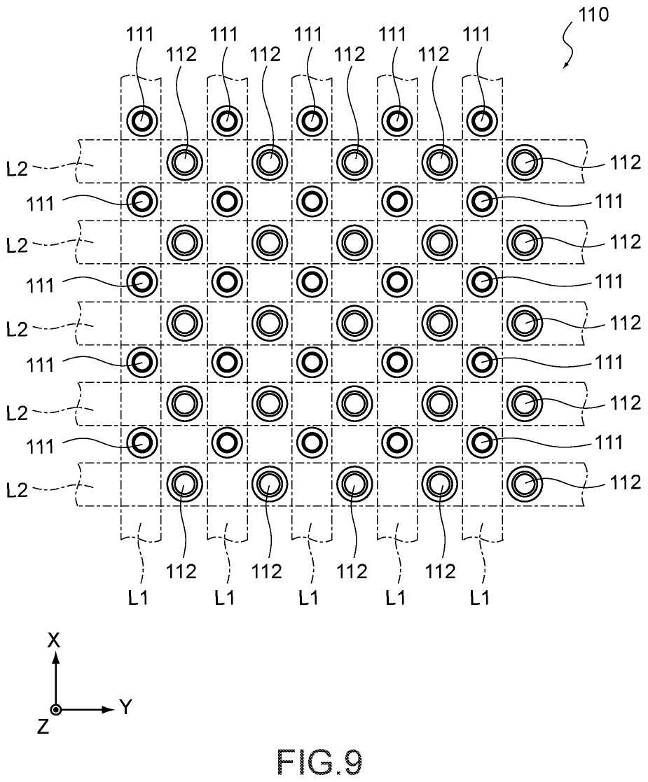

The first light-emitting elements 111 and the second light-emitting elements 112 are arranged on the light-emitting element surface 115. FIG. 9 is a schematic diagram showing arrangement of the first light-emitting elements 111 and the second light-emitting elements 112, and is a diagram of the light-emitting element surface 115 as viewed from a direction (Z direction) perpendicular to the light-emitting element surface 115 (X-Y plane). As shown in the figure, the first light-emitting elements 111 are arranged in one direction (X direction) parallel to the light-emitting element surface 115 (X-Y plane) to form respective first light-emitting element columns L1. Hereinafter, this arrangement direction (X direction) of the first light-emitting elements 111 will be referred to as a first arrangement direction. Further, the second light-emitting elements 112 are arranged along a direction (Y direction) parallel to the light-emitting element surface 115 (X-Y plane) and orthogonal to the first arrangement direction (X direction) to form respective second light-emitting element columns L2. Hereinafter, this arrangement direction (Y direction) of the second light-emitting elements 112 will be referred to as a second arrangement direction.

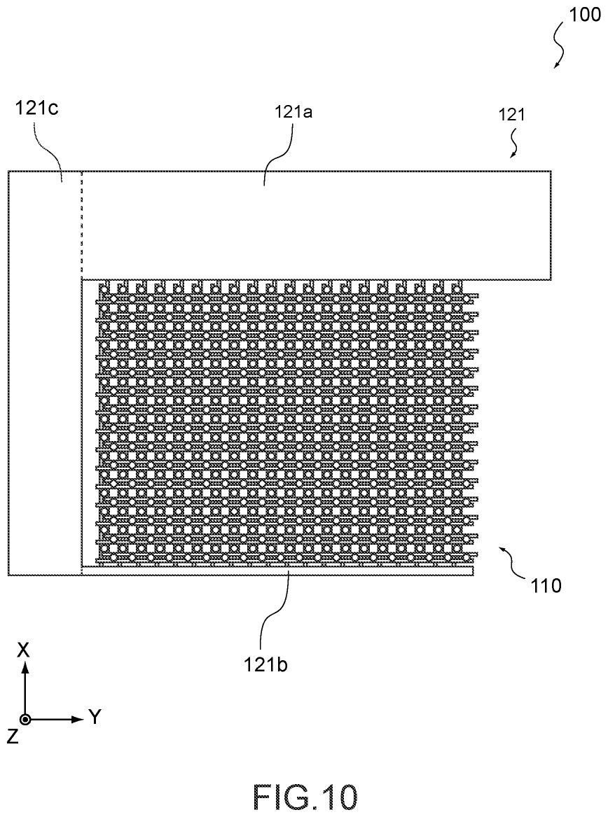

The first electrode pad 121 is an electrode pad for the first light-emitting elements 111 and is formed of a conductive material such as Au. FIG. 10 is a plan view showing the first electrode pad 121 and the light-emitting element group 110 and is a diagram showing a partial configuration of FIG. 1. As shown in the figure, the first electrode pad 121 includes a first portion 121a, a second portion 121b, and a connection portion 121c. The first portion 121a and the second portion 121a are located in opposite directions via the light-emitting element group 110 in a direction (X direction) parallel to the first arrangement direction, i.e., are disposed so as to sandwich the light-emitting element group 110 in the same direction (X direction). The connection portion 121c is provided between the first portion 121a and the second portion 121b and electrically connects the first portion 121a and the second portion 121b to each other.

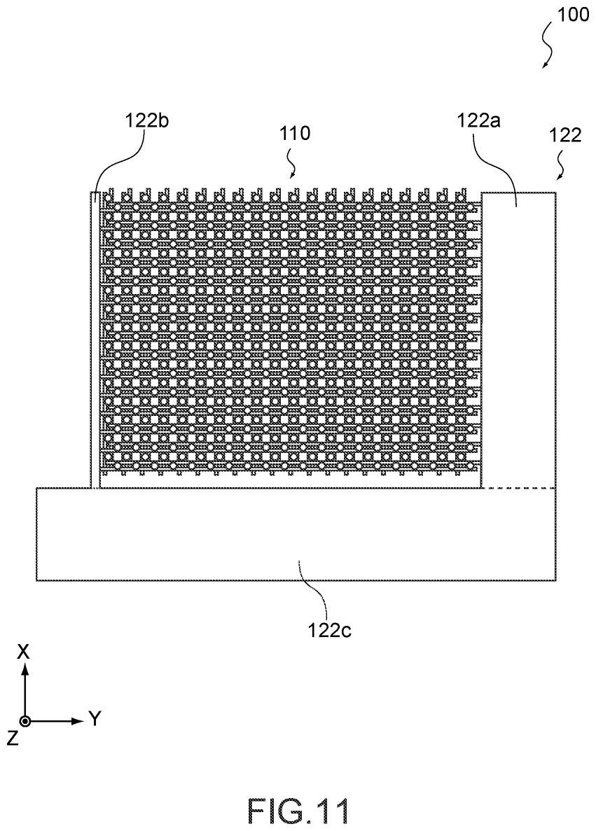

The second electrode pad 122 is an electrode pad for the second light-emitting elements 112 and is formed of a conductive material such as Au. FIG. 11 is a plan view showing the second electrode pad 122 and the light-emitting element group 110 and is a diagram showing a partial configuration of FIG. 1. As shown in the figure, the second electrode pad 122 includes a third portion 122a, a fourth portion 122b, and a connection portion 122c. The third portion 122a and the fourth portion 122b are located in opposite directions via the light-emitting element group 110 in a direction (Y direction) parallel to the second arrangement direction, i.e., are disposed so as to sandwich the light-emitting element group 110 in the same direction (Y direction). The connection portion 122c is provided between the third portion 122a and the fourth portion 122b and electrically connects the third portion 122a and the fourth portion 122b to each other.

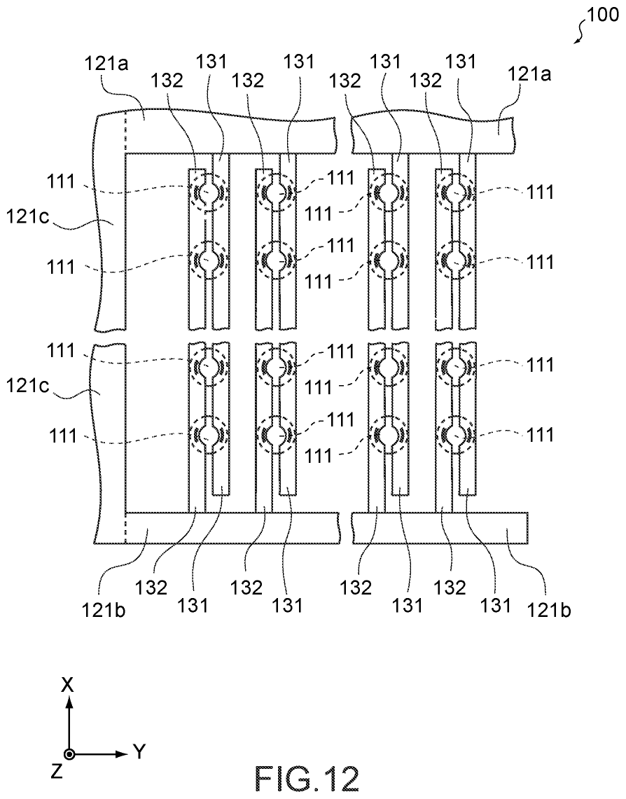

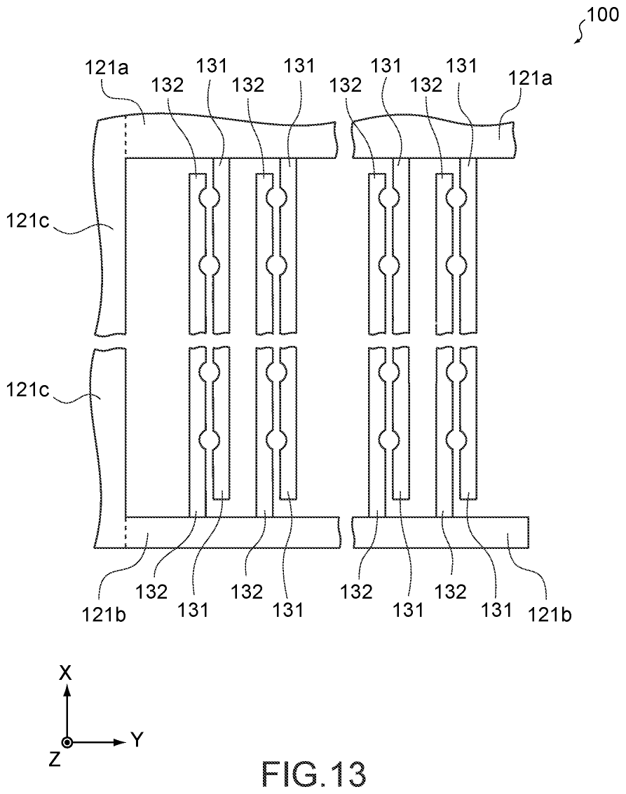

The first wire 131 and the second wire 132 are wires for the first light-emitting elements 111, are electrically connected to each of the first light-emitting elements 111 in each of the first light-emitting element columns L1, and are insulated from each of the second light-emitting elements 112. The first wire 131 and the second wire 132 are formed of a conductive material such as Au. FIG. 12 is a plan view showing a configuration relating to the first light-emitting elements 111 in FIG. 2, and FIG. 13 is a plan view in which illustration of the first light-emitting elements 111 in FIG. 12 is omitted. As shown in FIG. 13, the first wire 131 and the second wire 132 extend along a first extending direction (X direction) parallel to the first arrangement direction and are spaced apart from each other. The first wire 131 is connected to the first portion 121a of the first electrode pad 121 and spaced apart from the second portion 121b. The second wires 132 is connected to the second portion 121b of the first electrode pad 121 and spaced apart from the first portion 121a.

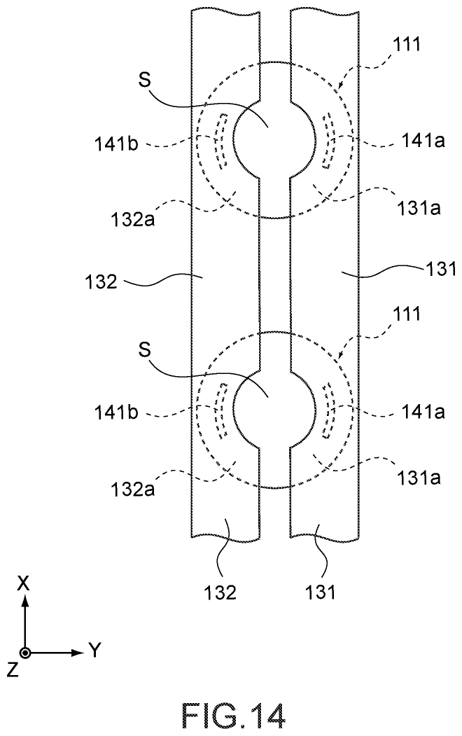

FIG. 14 is an enlarged view of FIG. 12. As shown in the figure, the first wire 131 and the second wire 132 are superimposed on the individual first light-emitting elements 111 as viewed from a direction (Z direction) perpendicular to the light-emitting element surface 115. Hereinafter, a region of the first wire 131 superimposed on the first light-emitting element 111 as viewed from the same direction (Z direction) will be referred to as a first superimposition region 131a. A first current injection port 141a described below is provided in the first superimposition region 131a, and the first wire 131 is electrically connected to the p-electrode 158 (see FIG. 7) of each first light-emitting element 111 via the first current injection port 141a.

Further, a region of the second wire 132 superimposed on the first light-emitting element 111 as viewed from a direction (Z direction) perpendicular to the light-emitting element surface 115 will be referred to as a second superimposition region 132a. A second current injection port 141b described below is provided in the second superimposition region 132a, and the second wire 132 is electrically connected to the p-electrode 158 (see FIG. 7) of each first light-emitting element 111 via the second current injection port 141b. Note that as shown in FIG. 13, the first wire 131 and the second wire 132 suitably have a shape in which a notch is provided on the light-emitting surface S. By adopting this shape, it is possible to increase the wire width of the first wire 131 and the second wire 132 without blocking the light-emitting surface S.

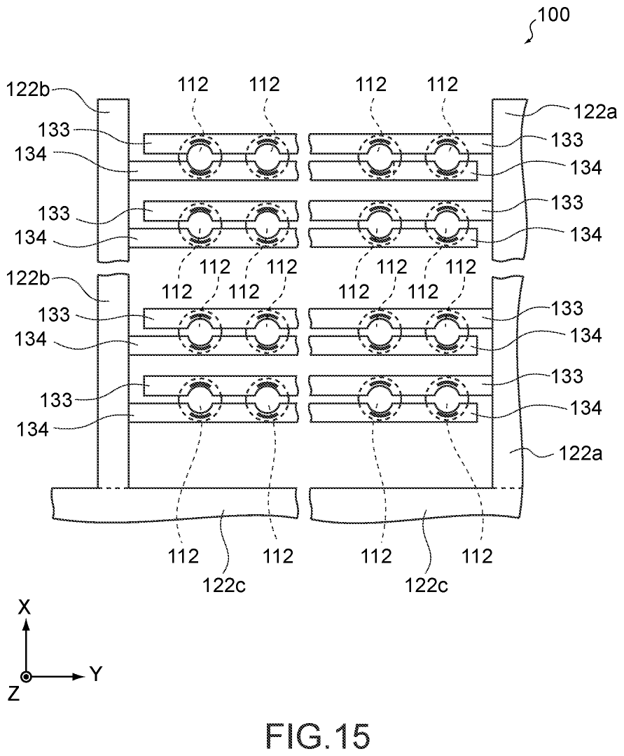

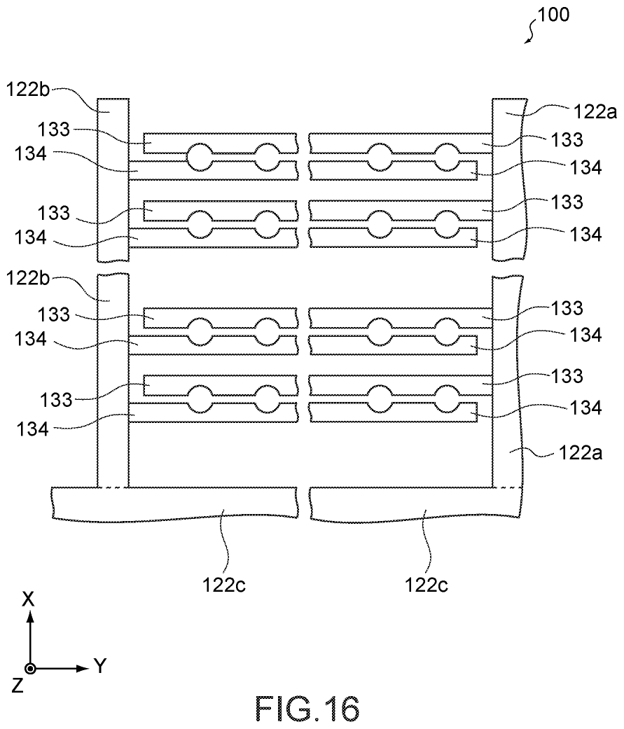

The third wire 133 and the fourth wire 134 are wires for the second light-emitting elements 112, are electrically connected to each of the second light-emitting elements 112 in each of the second light-emitting element columns L2, and are insulated from each of the first light-emitting elements 111. The third wire 133 and the fourth wire 134 are formed of a conductive material such as Au. FIG. 15 is a plan view showing a configuration relating to the second light-emitting elements 112 in FIG. 2, and FIG. 16 is a plan view in which illustration of the second light-emitting elements 112 is omitted in FIG. 15. As shown in FIG. 16, the third wire 133 and the fourth wire 134 extend along a second extending direction (Y direction) parallel to the second arrangement direction and are spaced apart from each other. The second extending direction (Y direction) is a direction orthogonal to the first extending direction (X direction). The third wire 133 is connected to the third portion 122a of the second electrode pad 122 and spaced apart from the fourth portion 122b. The fourth wire 134 is connected to the fourth portion 122b of the second electrode pad 122 and spaced apart from the third portion 122a.

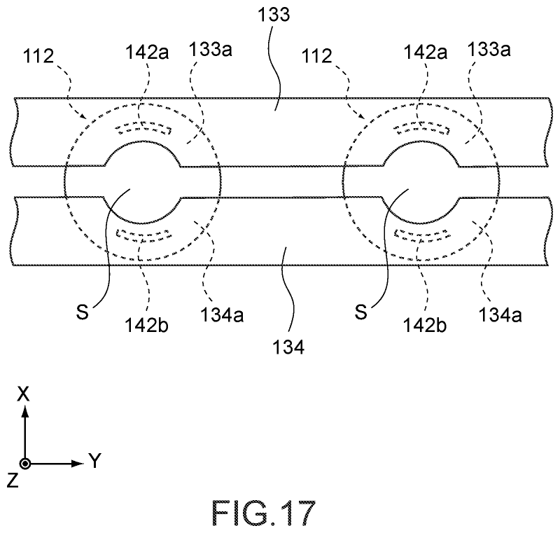

FIG. 17 is an enlarged view of FIG. 15. As shown in the figure, the third wire 133 and the fourth wire 134 are superimposed on the individual second light-emitting elements 112 as viewed from a direction (Z direction) perpendicular to the light-emitting element surface 115. Hereinafter, a region of the third wire 133 superimposed on the second light-emitting element 112 as viewed from the same direction (Z direction) will be referred to as a third superimposition region 133a. A third current injection port 142a described below is provided in the third superimposition region 133a, and the third wire 133 is electrically connected to the p-electrode 158 (see FIG. 7) of each second light-emitting element 112 via the third current injection port 142a.

Further, a region of the fourth wire 134 superimposed on the second light-emitting element 112 as viewed from a direction (Z direction) perpendicular to the light-emitting element surface 115 will be referred to as a fourth superimposition region 134a. A fourth current injection port 142b described below is provided in the fourth superimposition region 134a, and the fourth wire 134 is electrically connected to the p-electrode 158 (see FIG. 7) of each second light-emitting element 112 via the fourth current injection port 142b. Note that as shown in FIG. 16, the third wire 133 and the fourth wire 134 suitably have a shape in which a notch is provided on the light-emitting surface S. By adopting this shape, it is possible to increase the wire width of the third wire 133 and the fourth wire 134 without blocking the light-emitting surface S.

The light-emitting element array 100 has the wiring structure as described above. Note that the light-emitting element array 100 does not need to include all the above configurations, and only needs to include at least the first light-emitting elements 111, the first wires 131, and the second wires 132.

### [Stacked Structure of Light-Emitting Element Array]

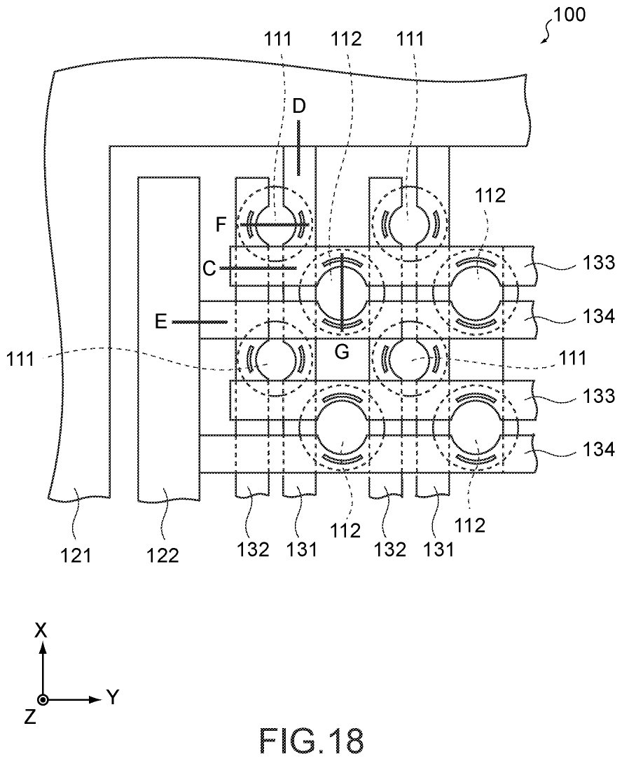

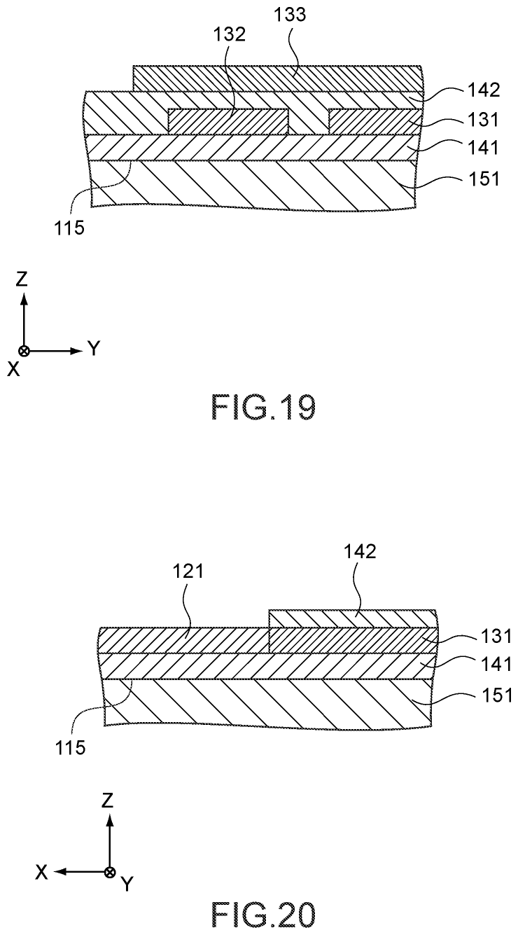

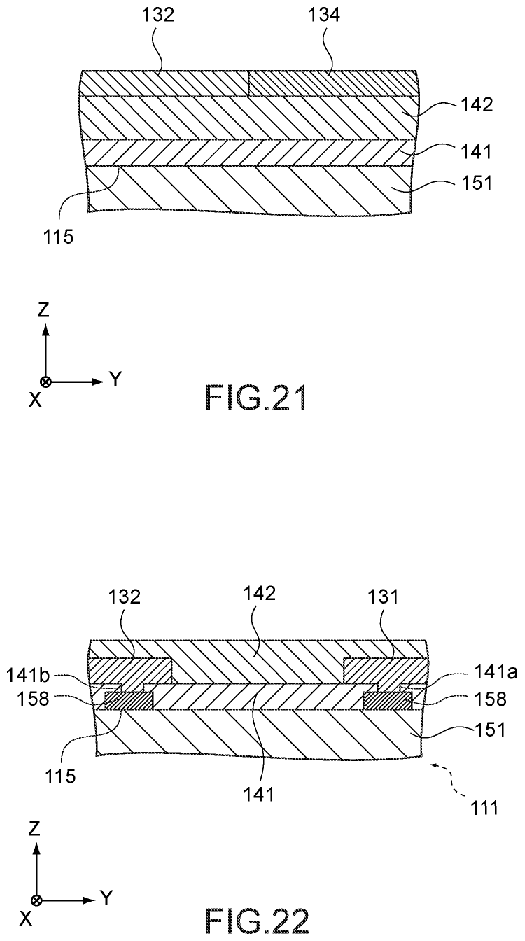

The stacked structure of the light-emitting element array 100 will be described. FIG. 18 is a schematic diagram showing a cross section of the light-emitting element array 100. FIG. 19 is a cross-sectional view of the light-emitting element array 100 taken along the line C in FIG. 18, FIG. 20 is a cross-sectional view of the light-emitting element array 100 taken along the line D in FIG. 18, and FIG. 21 is a cross-sectional view of the light-emitting element array 100 taken along the line E in FIG. 18. As shown in these figures, the light-emitting element array 100 may further include a first insulation layer 141 and a second insulation layer 142.

The first insulation layer 141 is formed of an insulating material, and is disposed on the light-emitting element surface 115 as shown in FIG. 19 to FIG. 21. As shown in FIG. 19, the first wire 131 and the second wire 132 are disposed on the first insulation layer 141. As shown in FIG. 20, the first electrode pad 121 is disposed on the first insulation layer 141. The second insulation layer 142 is formed of an insulating material, and is disposed on the first insulation layer 141, the first wire 131, and the second wire 132 as shown in FIG. 19 to FIG. 21. As shown in FIG. 20, the second insulation layer 142 is not disposed on the first electrode pad 121. As shown in FIG. 19 and FIG. 21, the third wire 133 and the fourth wire 134 are disposed on the second insulation layer 142.

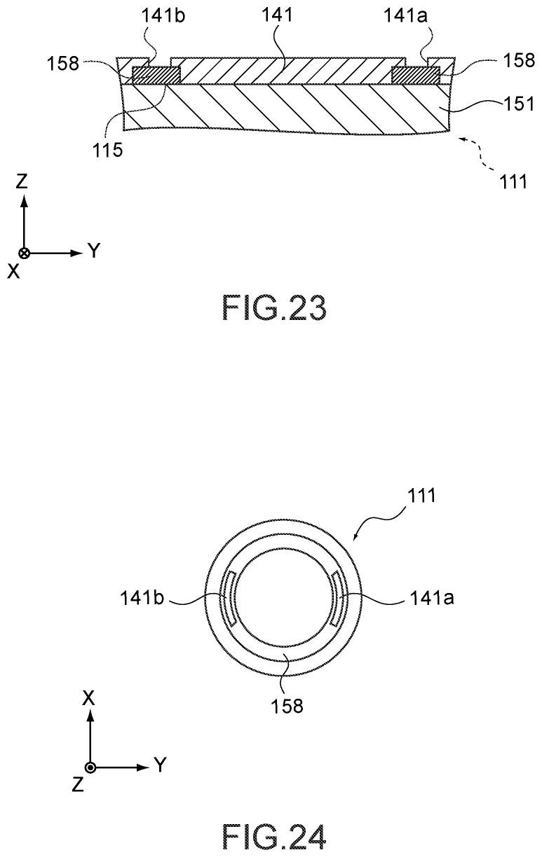

The first wire 131 and the second wire 132 are electrically connected to the first light-emitting elements 111 and are insulated from the second light-emitting elements 112 as described above. FIG. 22 is a cross-sectional view of the light-emitting element array 100 taken along the line F in FIG. 18, and FIG. 23 is a cross-sectional view showing a partial configuration of FIG. 22. As shown in FIG. 23, the first current injection port 141a and the second current injection port 141b, which are through holes, are provided in the first insulation layer 141. FIG. 24 is a schematic diagram showing a positional relationship between the first current injection port 141a, the second current injection port 141b, and the first light-emitting elements 111.

The first current injection port 141a is provided in the first superimposition region 131a (see FIG. 14) as described above, and is located on the p-electrode 158 of the first light-emitting element 111 as shown in FIG. 23 and FIG. 24. The second current injection port 141b is provided in the second superimposition region 132a (see FIG. 14) as described above, and is located on the p-electrode 158 of the first light-emitting element 111 as shown in FIG. 23 and FIG. 24. As shown in FIG. 22, the first wire 131 is in contact with the p-electrode 158 via the first current injection port 141a and electrically connected to the first light-emitting element 111. As shown in FIG. 22, the second wire 132 is in contact with the p-electrode 158 via the second current injection port 141b and electrically connected to the first light-emitting element 111. Although one first light-emitting element 111 has been illustrated here, the first wire 131 and the second wire 132 are electrically connected to the other first light-emitting elements 111, similarly.

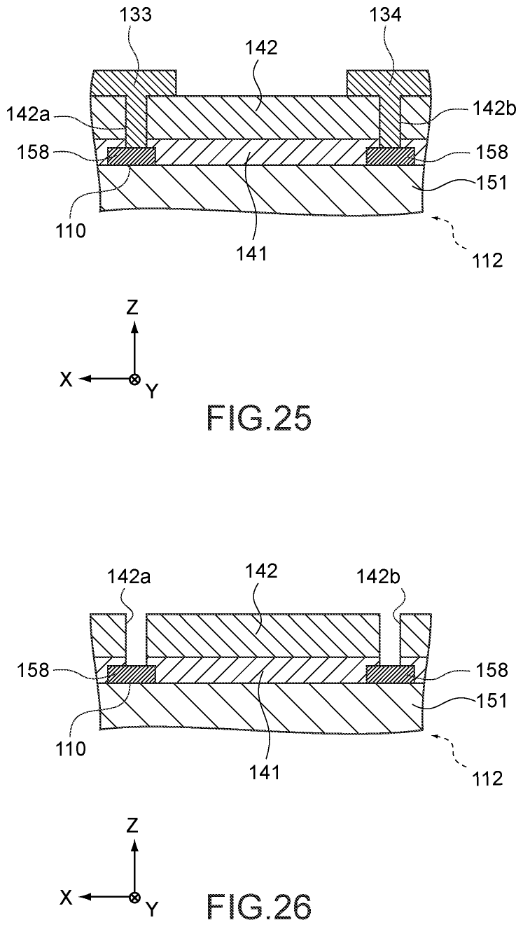

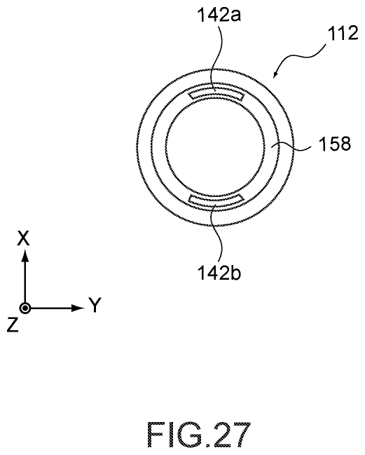

The third wire 133 and the fourth wire 134 are electrically connected to the second light-emitting elements 112 and insulated from the first light-emitting elements 111 as described above. FIG. 25 is a cross-sectional view of the light-emitting element array 100 taken along the line G in FIG. 18, and FIG. 26 is a cross-sectional view showing a partial configuration of FIG. 25. As shown in FIG. 26, the third current injection port 142a and the fourth current injection port 142b, which are through holes, are provided in the first insulation layer 141 and the second insulation layer 142. FIG. 27 is a schematic diagram showing a positional relationship of the third current injection port 142a, the fourth current injection port 142b, and the second light-emitting element 112.

The third current injection port 142a is provided in the third superimposition region 133a (see FIG. 17) as described above, and is located on the p-electrode 158 of the second light-emitting element 112 as shown in FIG. 26 and FIG. 27. The fourth current injection port 142b is provided in the fourth superimposition region 134a (see FIG. 17) as described above, and is located on the p-electrode 158 of the second light-emitting element 112 as shown in FIG. 26 and FIG. 27. As shown in FIG. 25, the third wire 133 is in contact with the p-electrode 158 via the third current injection port 142a and is electrically connected to the second light-emitting element 112. As shown in FIG. 25, the fourth wire 134 is in contact with the p-electrode 158 via the fourth current injection port 142b and is electrically connected to the second light-emitting element 112. Although one second light-emitting element 112 has been illustrated here, the third wire 133 and the fourth wire 134 are electrically connected to the other second light-emitting elements 112, similarly.

The light-emitting element array 100 has the stacked structure as described above. By making the light-emitting element array 100 have such a stacked structure, it is possible to insulate the first wire 131 and the second wire 132 from the third wire 133 and the fourth wire 134 between layers, and intersect the first wire 131 and the second wire 132 with the third wire 133 and the fourth wire 134 (see FIG. 2).

Although the method of forming the stacked structure of the light-emitting element array 100 is not particularly limited, it can be formed as follows. That is, after forming the light-emitting element group 110, the first insulation layer 141 is formed on the light-emitting element surface 115, and the first current injection port 141a and the second current injection port 141b (see FIG. 23) are formed at the above positions. The first current injection port 141a and the second current injection port 141b can be formed by removing the first insulation layer 141 by RIE (Reactive Ion Etching) or the like. Next, the first electrode pad 121, the first wires 131, and the second wires 132 are formed on the first insulation layer 141, and these wires are caused to be electrically connected to the first light-emitting elements 111 via the first current injection port 141a and the second current injection port 141b (see FIG. 22).

Next, the second insulation layer 142 is formed on the first insulation layer 141, the first electrode pad 121, the first wires 131, and the second wires 132, and the third current injection port 142a and the fourth current injection port 142b (see FIG. 26) are formed at the above positions. The third current injection port 142a and the fourth current injection port 142b can be formed by removing the second insulation layer 142 and the first insulation layer 141 by RIE or the like. At the same time, the first insulation layer 141 on the first electrode pad 121 is removed by RIE or the like to expose the first electrode pad 121 (see FIG. 20). Next, the second electrode pad 122, the third wires 133, and the fourth wires 134 are formed on the second insulation layer 142, and these wires are caused to be electrically connected to the second light-emitting elements 111 via the third current injection port 142a and the fourth current injection port 142b (see FIG. 25).

The light-emitting element array 100 can be mounted by wire bonding or the like. In the wire bonding, a drive signal wire of the first light-emitting element 111 can be bonded to the first portion 121a and the connection portion 121c (see FIG. 10), and a drive signal wire of the second light-emitting element 112 can be bonded to the third portion 122a and the connection portion 122c (see FIG. 11). Further, a drive signal wire of the first light-emitting element 111 may be bonded to the first portion 121a and the second portion 121b (see FIG. 10), and a drive signal wire of the second light-emitting element 112 may be bonded to the third portion 122a and the fourth portion 122b (see FIG. 11). The light-emitting element array 100 can also be mounted by other mounting methods.

### [Operation of Light-Emitting Element Array]

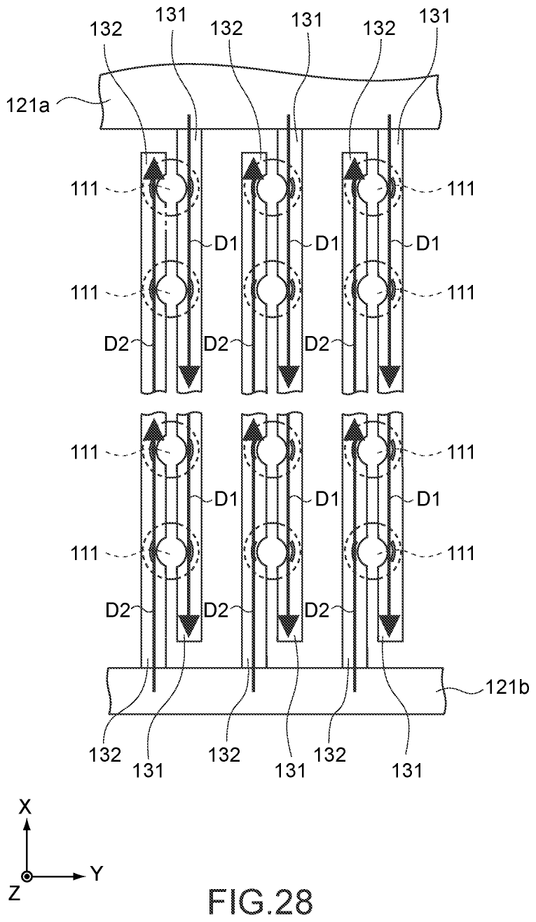

An operation of the light-emitting element array 100 will be described. FIG. 28 is a schematic diagram showing a drive current of the first light-emitting elements 111. When a voltage is applied to the first electrode pad 121, a current flows through the first wire 131 and the second wire 132. As described above, the first wire 131 is connected to the first portion 121a of the first electrode pad 121 and spaced apart from the second portion 121b. For this reason, the current flowing through the first wire 131 flows into the first wire 131 from the first portion 121a and flows through the first wire 131 toward the first light-emitting element 111 as shown by arrows in FIG. 28. Hereinafter, the orientation of the current flowing through the first wire 131 will be referred to as a first orientation D1. The first orientation D1 is parallel to the first extending direction (X direction) that is the extending direction of the first wire 131 and is an orientation from the first portion 121a toward the second portion 121b.

Further, the second wire 132 is connected to the second portion 121b of the first electrode pad 121 and spaced apart from the first portion 121a. For this reason, the current flowing through the second wire 132 flows into the second wire 132 from the second portion 121b as shown by arrows in FIG. 28 and flows through the second wire 132 toward each first light-emitting element 111. Hereinafter, the orientation of the current flowing through the second wire 132 will be referred to as a second orientation D2. The second orientation D2 is parallel to the first extending direction (X direction) that is the extending direction of the second wire 133 and is an orientation from the second portion 121b toward the first portion 121a. Therefore, the first orientation D1 and the second orientation D2 are orientations opposite to each other.

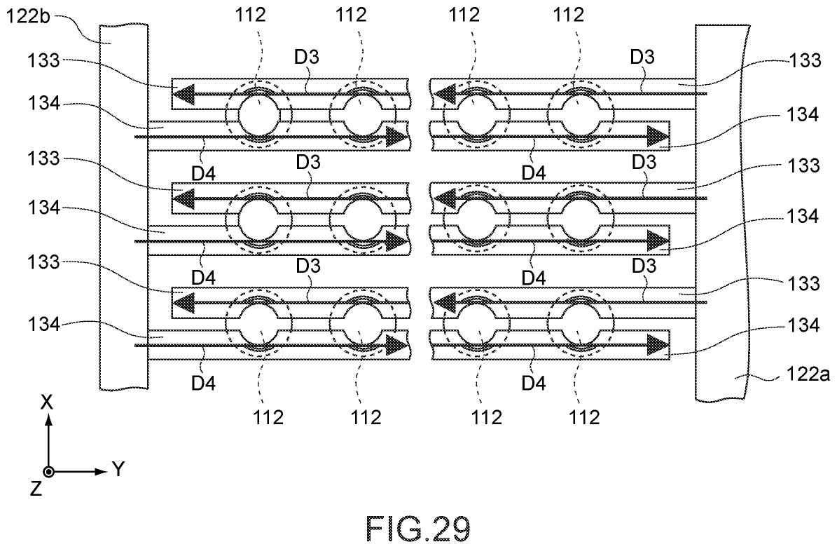

FIG. 29 is a schematic diagram showing a drive current of the second light-emitting elements 112. When a voltage is applied to the second electrode pad 121, a current flows through the third wire 133 and the fourth wire 134. As described above, the third wire 133 is connected to the third portion 122a of the second electrode pad 122 and spaced apart from the fourth portion 122b. For this reason, the current flowing through the third wire 133 flows into the third wire 133 from the third portion 122a as shown by arrows in FIG. 29 and flows through the third wire 133 toward each second light-emitting element 112. Hereinafter, the orientation of the current flowing through the third wire 133 will be referred to as a third orientation D3. The third orientation D3 is parallel to the second extending direction (Y direction) that is the extending direction of the third wire 133 and is an orientation from the third portion 122a toward the fourth portion 122b.

Further, the fourth wire 134 is connected to the fourth portion 122b of the second electrode pad 122 and spaced apart from the third portion 122a. For this reason, the current flowing through the fourth wire 134 flows into the fourth wire 134 from the fourth portion 122b as shown by arrows in FIG. 29 and flows through the fourth wire 134 toward each second light-emitting element 112. Hereinafter, the orientation of the current flowing through the fourth wire 134 will be referred to as a fourth orientation D4. The fourth orientation D4 is parallel to the second extending direction (Y direction) that is the extending direction of the fourth wire 134 and is an orientation from the fourth portion 122b toward the third portion 122a. Therefore, the third orientation D3 and the fourth orientation D4 are orientations opposite to each other.

The first light-emitting element 111 and the second light-emitting element can be caused to emit light separately. When a voltage is applied to the first electrode pad 121, a current in the first orientation D1 flows through the first wire 131, and at the same time, a current in the second orientation D2 flows through the second wire 132. As a result, each first light-emitting element 111 electrically connected to the first wire 131 and the second wire 132 emits light. Further, when a voltage is applied to the second electrode pad 122, a current in the third orientation D3 flows through the third wire 133, and at the same time, a current in the fourth orientation D4 flows through the fourth wire 134. As a result, each second light-emitting element 112 electrically connected to the third wire 133 and the fourth wire 134 emits light.

### [Effects of Light-Emitting Element Array]

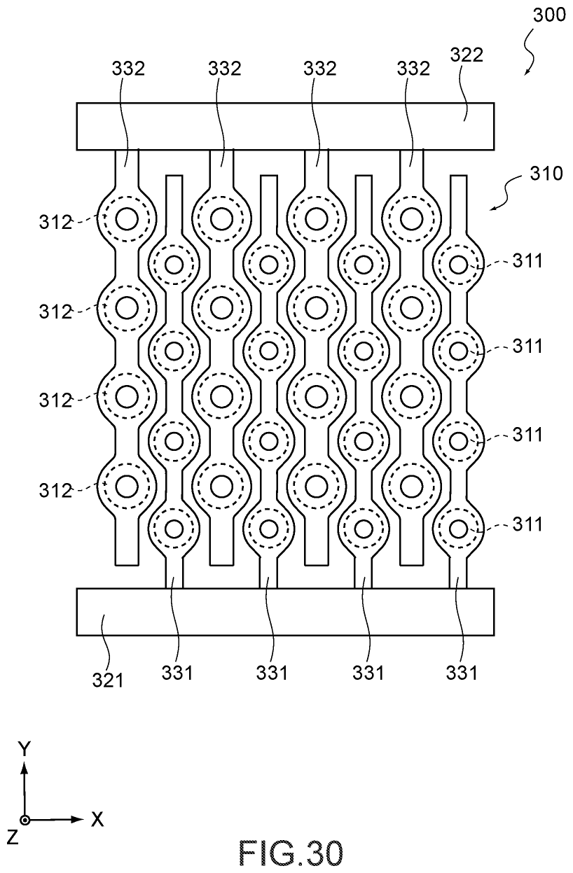

The effects of the light-emitting element array 100 will be described in comparison with Comparative Example. FIG. 30 is a schematic diagram of a light-emitting element array 300 according to Comparative Example. As shown in the figure, the light-emitting element array 300 includes first light-emitting elements 311, second light-emitting elements 312, a first electrode pad 321, a second electrode pad 322, first wires 331, and second wires 332. The first light-emitting elements 311 and the second light-emitting elements 312 constitute a light-emitting element group 310.

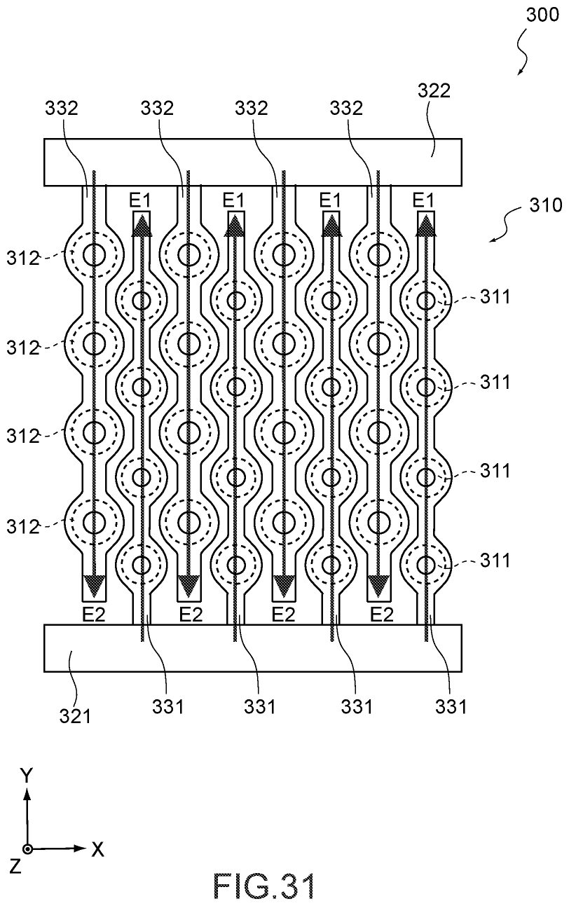

The first electrode pad 321 and the second electrode pad 322 are disposed on the opposite sides via the light-emitting element group 310. The first wire 331 extends from the first electrode pad 321 and is electrically connected to each first light-emitting element 311. The second wire 332 extends from the second electrode pad 322 and is electrically connected to each second light-emitting element 312. FIG. 31 is a schematic diagram showing orientations of currents in the light-emitting element array 300. As shown in the figure, a current in a first orientation E1 flows through the first wire 331 from the first electrode pad 321 and is supplied to each first light-emitting element 311. Further, a current in a second orientation E2 flows through the second wire 332 from the second electrode pad 322 and is supplied to each second light-emitting element 312. The first orientation E1 and the second orientation E2 are orientations opposite to each other.

Here, since only the current in the first orientation E1 is supplied to the first light-emitting element 311, the arrival of the current to the first light-emitting element 311 far from the first electrode pad 321 is delayed. Similarly, since only the current in the second orientation E2 is supplied to the second light-emitting elements 312, the arrival of the current to the second light-emitting element 312 far from the second electrode pad 322 is delayed. For this reason, in the configuration of the light-emitting element array 300, a decrease in the response speed of the first light-emitting element 311 and the second light-emitting element 312 becomes a problem.

Meanwhile, in the light-emitting element array 100 according to this embodiment, currents in both the first orientation D1 and the second orientation D2 are supplied to the first light-emitting elements 111 as shown in FIG. 28. For this reason, the current in the second orientation D2 is supplied from the second portion 121b to the first light-emitting element 111 far from the first portion 121a, and the current in the first orientation D1 is supplied from the first portion 121a to the first light-emitting element 111 far from the second portion 121b. As a result, the delay in the arrival of the current to the first light-emitting element 111 far from the first electrode pad 121 is suppressed, and the response speed is improved. Further, the first wire 131 and the second wire 132 are close to each other, and the first orientation D1 and the second orientation D2 are orientations opposite to each other. For this reason, the current in the first orientation D1 and the current in the second orientation D2 cancel each other's magnetic fields, and the effect of reducing the inductance is achieved. This reduction in inductance also improves the response speed.

Also regarding the second light-emitting elements 112, as shown in FIG. 29, currents in both the third orientation D3 and the fourth orientation D4 are supplied to the second light-emitting elements 112. For this reason, the current in the fourth orientation D4 is supplied from the fourth portion 122b to the second light-emitting element 112 far from the third portion 122a, and the current in the third orientation D3 is supplied from the third portion 122a to the second light-emitting element 112 far from the fourth portion 122b. As a result, the delay in the arrival of the current to the second light-emitting element 112 far from the second electrode pad 122 is suppressed, and the response speed is improved. Further, the third wire 133 and the fourth wire 134 are close to each other, and the third orientation D3 and the fourth orientation D4 are orientations opposite to each other. For this reason, the current in the third orientation D3 and the current in the fourth orientation D4 cancel each other's magnetic fields, and the effect of reducing the inductance is achieved. This reduction in inductance also improves the response speed. In this way, in the light-emitting element array 100, it is possible to improve the response speed of the first light-emitting elements 111 and the second light-emitting elements 112.

Further, in the light-emitting element array 100, the first wires 131 and the second wires 132 are disposed in a layer different from that of the third wires 133 and the fourth wires 134 (see FIG. 19). For this reason, it is possible to increase the width of each wire as compared with the case where the wires are disposed in the same layer. As a result, it is possible to reduce the drive voltage of each of the first light-emitting elements 111 and the second light-emitting elements 112.

### Modified Example

Although the light-emitting element array 100 includes the first light-emitting elements 111 and the second light-emitting elements 112 in the above description, it may include only the first light-emitting elements 111. In this case, the light-emitting element array 100 may include only the first light-emitting elements 111, the first electrode pad 121, the first wires 131, and the second wires 132.

Further, although the first extending direction that is the extending direction of the first wires 131 and the second wires 132 and the second extending direction that is the extending direction of the third wires 133 and the fourth wires 134 are orthogonal to each other (see FIG. 3) in the above description, the present technology is not limited thereto. For example, the first extending direction and the second extending direction may intersect at an angle of 80°, 45°, or the like. Further, although the first light-emitting element 111 and the second light-emitting element 112 have a mesa structure (see FIG. 8) in which the mesa 153 is formed in the above description, the present technology is not limited thereto. The first light-emitting element 111 and the second light-emitting element 112 may have a light-emitting structure other than the mesa structure.

### [Usage Example of Light-Emitting Element Array]

The light-emitting element array 100 is capable of causing the first light-emitting element 111 and the second light-emitting element 112 to emit light independently as described above and can be used for a ranging light source device capable of emitting light for short distances and light for long distances.

### [Regarding Present Disclosure]

The effects described in the present disclosure are merely examples and are not limited, and additional effects may be exerted. The description of the plurality of effects described above does not necessarily mean that these effects are exhibited simultaneously. It means that at least one of the effects described above can be achieved in accordance with the conditions or the like, and there is a possibility that an effect that is not described in the present disclosure is exerted. Further, at least two feature portions of the feature portions described in the present disclosure may be arbitrarily combined with each other.

It should be noted that the present technology may also take the following configurations.

(1) A light-emitting element array, including:
a light-emitting element group that forms a light-emitting element surface on which a plurality of light-emitting elements is arranged in a planar shape and includes first light-emitting element columns, first light-emitting elements included in the plurality of light-emitting elements being arranged along a first direction parallel to the light-emitting element surface in each of the first light-emitting element columns;
a first wire that extends along the first direction and is electrically connected to each of the first light-emitting elements in each of the first light-emitting element columns, a current flowing through the first wire in a first orientation parallel to the first direction; and
a second wire that extends along the first direction and is electrically connected to each of the first light-emitting elements in each of the first light-emitting element columns, a current flowing through the second wire in a second orientation parallel to the first direction and opposite to the first orientation.

(2) The light-emitting element array according to (1) above, in which
the light-emitting element group further includes second light-emitting element columns, second light-emitting elements included in the plurality of light-emitting elements being arranged along a second direction parallel to the light-emitting element surface in each of the second light-emitting element columns, the light-emitting element array further including:
a third wire that extends along the second direction and is electrically connected to each of the second light-emitting elements in each of the second light-emitting element columns, a current flowing through the third wire in a third orientation parallel to the second direction; and
a fourth wire that extends along the second direction and is electrically connected to each of the second light-emitting elements in each of the second light-emitting element columns, a current flowing through the fourth wire in a fourth orientation parallel to the second direction and opposite to the third orientation.

(3) The light-emitting element array according to (2) above, in which
the first direction and the second direction are orthogonal to each other.

(4) The light-emitting element array according to (2) or (3) above, further including:
a first insulation layer formed of an insulating material; and
a second insulation layer formed of an insulating material,
the first insulation layer being disposed on the light-emitting element surface,
the first wire and the second wire being disposed on the first insulation layer,
the second insulation layer being formed on the first insulation layer, the first wire, and the second wire,
the third wire and the fourth wire being disposed on the second insulation layer.

(5) The light-emitting element array according to (4) above, in which
the first wire is electrically connected to each of the first light-emitting elements via a first current injection port provided in the first insulation layer,
the second wire is electrically connected to each of the first light-emitting elements via a second current injection port provided in the first insulation layer,
the third wire is electrically connected to each of the second light-emitting elements via a third current injection port provided in the first insulation layer and the second insulation layer, and
the fourth wire is electrically connected to each of the second light-emitting elements via a fourth current injection port provided in the first insulation layer and the second insulation layer.

(6) The light-emitting element array according to (5) above, in which
the first wire has a first superimposition region that is superimposed on the first light-emitting elements as viewed from a direction perpendicular to the light-emitting element surface, the first current injection port being provided within the first superimposition region as viewed from the direction,
the second wire has a second superimposition region that is superimposed on the first light-emitting elements as viewed from a direction perpendicular to the light-emitting element surface, the second current injection port being provided within the second superimposition region as viewed from the direction,
the third wire has a third superimposition region that is superimposed on the second light-emitting elements as viewed from a direction perpendicular to the light-emitting element surface, the third current injection port being provided within the third superimposition region as viewed from the direction, and
the fourth wire has a fourth superimposition region that is superimposed on the second light-emitting elements as viewed from a direction perpendicular to the light-emitting element surface, the fourth current injection port being provided within the fourth superimposition region as viewed from the direction.

(7) The light-emitting element array according to any one of (1) to (6) above, further including
a first electrode pad that is electrically connected to the first wire and the second wire and includes a first portion and a second portion, the first portion and the second portion being located in opposite directions via the light-emitting element group in the first direction,
the first wire being connected to the first portion and spaced apart from the second portion,
the second wire being connected to the second portion and spaced apart from the first portion.

(8) The light-emitting element array according to any one of (2) to (6) above, further including:
a first electrode pad that is electrically connected to the first wire and the second wire and includes a first portion and a second portion, the first portion and the second portion being located in opposite directions via the light-emitting element group in the first direction; and
a second electrode pad that is electrically connected to the third wire and the fourth wire and includes a third portion and a fourth portion, the third portion and the fourth portion being located in opposite directions via the light-emitting element group in the second direction,
the first wire being connected to the first portion and spaced apart from the second portion,
the second wire being connected to the second portion and spaced apart from the first portion,
the third wire being connected to the third portion and spaced apart from the fourth portion,
the fourth wire being connected to the fourth portion and spaced apart from the third portion.

(9) The light-emitting element array according to any one of (1) to (8) above, in which
each of the plurality of light-emitting elements is a vertical cavity surface emitting laser element.

### REFERENCE SIGNS LIST

100 light-emitting element array
110 light-emitting element group
111 first light-emitting element
112 second light-emitting element
115 light-emitting element surface
121 first electrode pad
122 second electrode pad
131 first wire
132 second wire
133 third wire
134 fourth wire
141 first insulation layer
142 second insulation layer
150 light-emitting element

1. A light-emitting element array, comprising:
a light-emitting element group that forms a light-emitting element surface on which a plurality of light-emitting elements is arranged in a planar shape and includes first light-emitting element columns, first light-emitting elements included in the plurality of light-emitting elements being arranged along a first direction parallel to the light-emitting element surface in each of the first light-emitting element columns;
a first wire that extends along the first direction and is electrically connected to each of the first light-emitting elements in each of the first light-emitting element columns, a current flowing through the first wire in a first orientation parallel to the first direction; and
a second wire that extends along the first direction and is electrically connected to each of the first light-emitting elements in each of the first light-emitting element columns, a current flowing through the second wire in a second orientation parallel to the first direction and opposite to the first orientation.

2. The light-emitting element array according to claim 1, wherein
the light-emitting element group further includes second light-emitting element columns, second light-emitting elements included in the plurality of light-emitting elements being arranged along a second direction parallel to the light-emitting element surface in each of the second light-emitting element columns, the light-emitting element array further comprising:
a third wire that extends along the second direction and is electrically connected to each of the second light-emitting elements in each of the second light-emitting element columns, a current flowing through the third wire in a third orientation parallel to the second direction; and
a fourth wire that extends along the second direction and is electrically connected to each of the second light-emitting elements in each of the second light-emitting element columns, a current flowing through the fourth wire in a fourth orientation parallel to the second direction and opposite to the third orientation.

3. The light-emitting element array according to claim 2, wherein
the first direction and the second direction are orthogonal to each other.

4. The light-emitting element array according to claim 2, further comprising:
a first insulation layer formed of an insulating material; and
a second insulation layer formed of an insulating material,
the first insulation layer being disposed on the light-emitting element surface,
the first wire and the second wire being disposed on the first insulation layer,
the second insulation layer being formed on the first insulation layer, the first wire, and the second wire,
the third wire and the fourth wire being disposed on the second insulation layer.

5. The light-emitting element array according to claim 4, wherein
the first wire is electrically connected to each of the first light-emitting elements via a first current injection port provided in the first insulation layer,
the second wire is electrically connected to each of the first light-emitting elements via a second current injection port provided in the first insulation layer,
the third wire is electrically connected to each of the second light-emitting elements via a third current injection port provided in the first insulation layer and the second insulation layer, and
the fourth wire is electrically connected to each of the second light-emitting elements via a fourth current injection port provided in the first insulation layer and the second insulation layer.

6. The light-emitting element array according to claim 5, wherein
the first wire has a first superimposition region that is superimposed on the first light-emitting elements as viewed from a direction perpendicular to the light-emitting element surface, the first current injection port being provided within the first superimposition region as viewed from the direction,
the second wire has a second superimposition region that is superimposed on the first light-emitting elements as viewed from a direction perpendicular to the light-emitting element surface, the second current injection port being provided within the second superimposition region as viewed from the direction,
the third wire has a third superimposition region that is superimposed on the second light-emitting elements as viewed from a direction perpendicular to the light-emitting element surface, the third current injection port being provided within the third superimposition region as viewed from the direction, and
the fourth wire has a fourth superimposition region that is superimposed on the second light-emitting elements as viewed from a direction perpendicular to the light-emitting element surface, the fourth current injection port being provided within the fourth superimposition region as viewed from the direction.

7. The light-emitting element array according to claim 1, further comprising
a first electrode pad that is electrically connected to the first wire and the second wire and includes a first portion and a second portion, the first portion and the second portion being located in opposite directions via the light-emitting element group in the first direction,
the first wire being connected to the first portion and spaced apart from the second portion,
the second wire being connected to the second portion and spaced apart from the first portion.

8. The light-emitting element array according to claim 2, further comprising:
a first electrode pad that is electrically connected to the first wire and the second wire and includes a first portion and a second portion, the first portion and the second portion being located in opposite directions via the light-emitting element group in the first direction; and
a second electrode pad that is electrically connected to the third wire and the fourth wire and includes a third portion and a fourth portion, the third portion and the fourth portion being located in opposite directions via the light-emitting element group in the second direction,
the first wire being connected to the first portion and spaced apart from the second portion,
the second wire being connected to the second portion and spaced apart from the first portion,
the third wire being connected to the third portion and spaced apart from the fourth portion,
the fourth wire being connected to the fourth portion and spaced apart from the third portion.

9. The light-emitting element array according to claim 1, wherein
each of the plurality of light-emitting elements is a vertical cavity surface emitting laser element.
